(19) United States
(12) Patent Application Publication
(10) Pub. No.: US 2007/0175585 A1
(43) Pub. Date: Aug. 2, 2007

(54) System and method for manufacturing process with fluid

(75) Inventor: Yi-Cheng Wang, Hsinchu City (TW)

Correspondence Address: BACON & THOMAS, PLLC, 625 SLATERS LANE, FOURTH FLOOR, ALEXANDRIA, VA, 22314, US

(73) Assignee: PERFECT DYNASTY TAIWAN LTD., Hsinchu City (TW)

(21) Appl. No.: 11/342,550

(22) Filed: Jan. 31, 2006

(51) Int. Cl. H01L 21/306

(52) U.S. Cl. 156/345.1

(57) ABSTRACT

A system and a method for manufacturing process is provided, in which the fluid used to process the processed component is also used to move the processed component through the steps during the process. The system includes a chemical supply unit, a processing platform, and a control unit. The chemical supply unit is a device for supplying a chemical fluid to react with the processed component, as well as clean water or air that may be required in the process. The processing platform receives the chemical fluid, water and air from the chemical supply unit and provides a processing environment to process the processed component. The processing platform is designed to work with the chemical supply unit so that the chemical fluid can be supplied to the processing platform to move and react with the processed component. The control unit is a programmable electronic device. The control unit controls the operations of both the chemical supply unit and the processing platform by inputting the parameters required for the manufacturing process.

### FIELD OF THE INVENTION

The present invention generally relates to a system and a method for a manufacturing process, and more specifically to a system and method for a manufacturing process with the movement of the processed component powered by fluid. The present invention is applicable to manufacturing process for chemical cleaning, etching, drying, surface processing, and other special manufacturing processes.

### BACKGROUND OF THE INVENTION

Conventional manufacturing processes usually need to move the processed component through a sequence of processing steps, such as cleaning, etching, electroplating, drying, heating, chilling, diffusion, hardening, and so on. Many conventional manufacturing systems use a motor and a transmission axis to provide the power that is required for conveying or rotating the processed component.

FIG. 1 shows a schematic view of a conventional manufacturing system, including a processing platform 110, a chemical supply unit 120 and a power supply device 130. Processing platform 110 includes a rotating platform 111 and a sink 112. A processed component 140 is placed in rotating platform 110 for processing. Chemical supply unit 120 is connected to a plurality of chambers 121 containing chemical fluids required for manufacturing processes. The chemical fluid is supplied through chemical supply unit 120 to react with processed component 140 on rotating platform 111, and flows into sink 112 after the reaction process. Power supply device 130 includes a motor 131 and a transmission axis 132, which provides power to rotate rotating platform 111.

A drawback of the above conventional manufacturing system is that the presence of an extra power supply device makes the manufacturing system bulkier, and usually difficult to stack the processing platform so save space. In addition, the power supply device increases the manufacturing cost to the manufacturing process. It is therefore imperative to provide a manufacturing system that can improve the power supply mechanism to increase the manufacturing efficiency.

### SUMMARY OF THE INVENTION

The present invention has been made to overcome the above-mentioned drawback of conventional manufacturing systems that use a motor power supply device. The primary object of the present invention is to provide a manufacturing system and a method that uses the chemical fluid to provide the power to move the processed component through the manufacturing process.

Another object of the present invention is to provide a manufacturing system and a method that is efficient in operation space so that a plurality of processing platforms can be stacked to save space.

Yet another object is to provide a manufacturing system and a method that is simple in structure and inexpensive in manufacturing.

To achieve the aforementioned objects, the present invention provides a system and a method for manufacturing process in which the fluid used to process the processed component is also used to move the processed component through the steps during the process. The system includes a chemical supply unit, a processing platform, and a control unit. The chemical supply unit is a device for supplying a chemical fluid to react with the processed component, as well as clean water or air that may be required in the process. The processing platform receives the chemical fluid, water and air from the chemical supply unit and provides a processing environment to process the processed component. The processing platform is designed to work with the chemical supply unit so that the chemical fluid can be supplied to the processing platform to move and react with the processed component. The control unit is a programmable electronic device. The control unit controls the operations of both the chemical supply unit and the processing platform by inputting the parameters required for the manufacturing process.

By injecting the fluid with a specific flow and direction between the processing platform and the processed component, the flowing fluid with move the processed component because of the Bernoulli effect, which states that the flowing fluid will draw the two surfaces closer. If one of the surfaces is stationary, or the surfaces have different surface characteristics, such as roughness, the fluid will create different acceleration forces to the two surfaces, which leads to a relative velocity between the two surfaces. In addition, the boundary layer between the surfaces and the fluid becomes thinner because of the relative velocity, which also accelerates the reaction speed or the temperature propagation. When the pressure, flow volume, injection location, direction and temperature of the fluid are appropriately controlled, the manufacturing system can be applied to a plurality of manufacturing processes without the use of a motor-driven transmission axis to supply the movement power.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a conventional motor-driven manufacturing system;

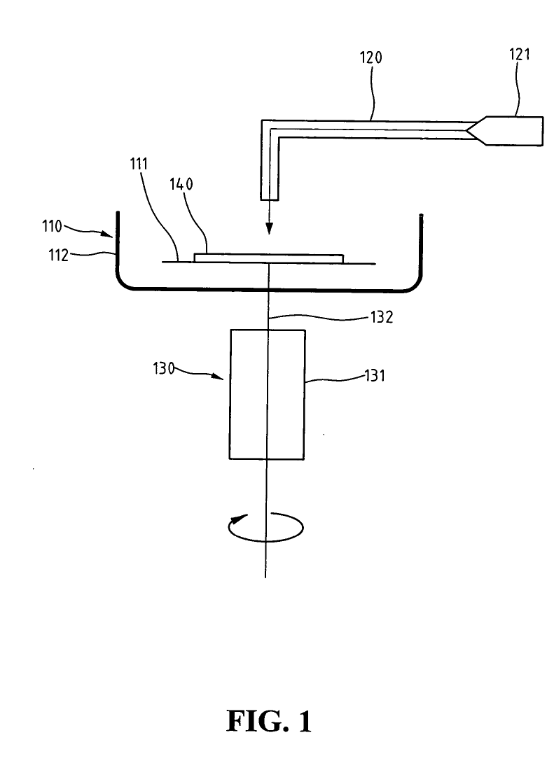

FIG. 2 shows a system block diagram of a manufacturing system of the present invention;

FIGS. 3A and 3B show respectively a top cross-sectional view and a top view of a circular processing platform of the present invention;

FIG. 4 shows a top view of a straight conveyor processing platform of the present invention;

FIG. 5 shows a top view of another embodiment of processing platform of the present invention;

FIG. 6 shows a dual-side processing platform of the present invention;

FIG. 7 shows a stacked dual-size processing platform of the present invention; and

FIG. 8 shows another application of the present invention.

### DETAILED DESCRIPTION OF THE PREFERRED EMBODIMENTS

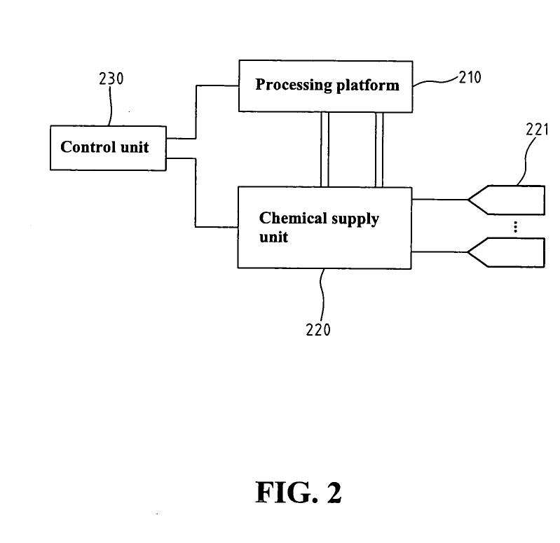

FIG. 2 shows a schematic view of a manufacturing system of the present invention, including a processing platform 210, a chemical supply unit 220, and a control unit 230. Processing platform 210 provides an environment where a processed component (not shown) is processed. Chemical supply unit 220 is connected to a plurality of chambers 221 containing, chemical fluids, water, air and so on. Chemical supply unit 220 a device for supplying chemical fluids to processing platform 210 react with the processed component, as well as clean water or air that may be required for the manufacturing the process. The reacted chemical fluids and water in processing platform 210 can also be collected by chemical supply unit 220. Chemical supply unit 220 is designed to work with processing platform 210 so that the chemical fluids supplied to processing platform not only reacts with the processed component, but also provide the force to move or rotate the processed component as the manufacturing process needs. Control unit 230 is a programmable electronic device, and controls the operations of both chemical supply unit 220 and processing platform 210 by inputting the parameters required for the manufacturing process. Control unit 230 can perform a various controls, such as process control, temperature control, flow volume control, fluid injection and location, and so on.

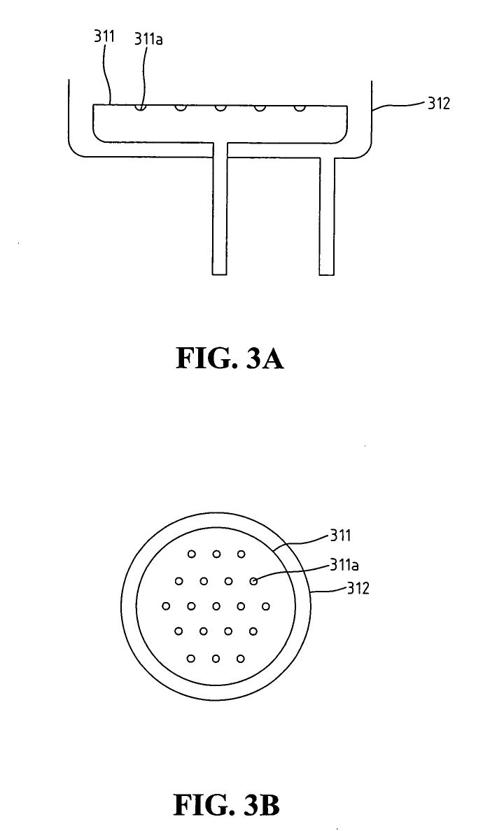

FIGS. 3A and 3B show respectively a cross-sectional view and a top view of an embodiment of a circular processing platform of the present invention. As shown in FIGS. 3A and 3B, a circular processing platform includes a rotating platform 311, and a sink 312. Rotating platform 311 is a platform for laying the processed component during the manufacturing process. Rotating platform 311 includes a plurality of injection spraying elements 311a from which the chemical fluids, water or air can be injected between the processed component and rotating platform 311 for chemical reaction, cleaning or drying. There is a trench between rotating platform 311 and sink 312 for collecting reacted or overflowed fluids. The collected fluids are fed to chemical supply unit 220 of FIG. 2 for further processing, re-use, or disposal. The arrangement, such as location and direction, of injection spraying elements 311a on rotating platform 311 is designed to match the manufacturing process so that the processed component can be rotated and moved through various process steps.

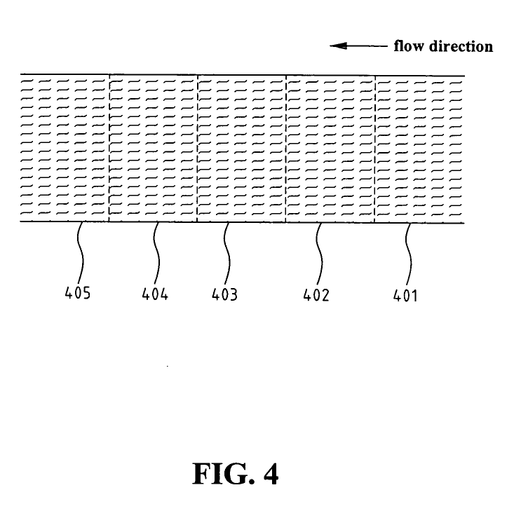

FIG. 4 shows a schematic view of an embodiment of a processing platform with a straight movement similar to a conveyor, including a feed-in area 401, a chemical processing area 402, a cleaning processing area 403, a drying processing area 404, and an output area 405. As shown in FIG. 4, the processed component moves from feed-in area 401, through chemical processing area 402, cleaning processing area 403, drying processing area 404, and reaches output area 405. The processed component can be a flat glass, a PCB or other types of equivalent components.

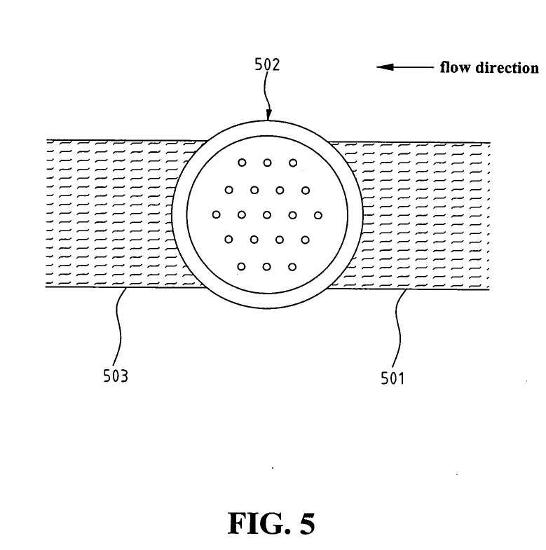

FIG. 5 shows an embodiment of a processing platform with a circular rotating platform of FIGS. 3A and 3B complemented with two segments of straight conveyor movement, including a feed-in area 501, a rotating platform 502, and an output area 503. In this embodiment, a component for processing moves from feed-in area 501, through rotating platform 502, and reaches output area 503. Rotating platform 502 provides the environment for various manufacturing processes, including chemical processing, cleaning processing and drying processing.

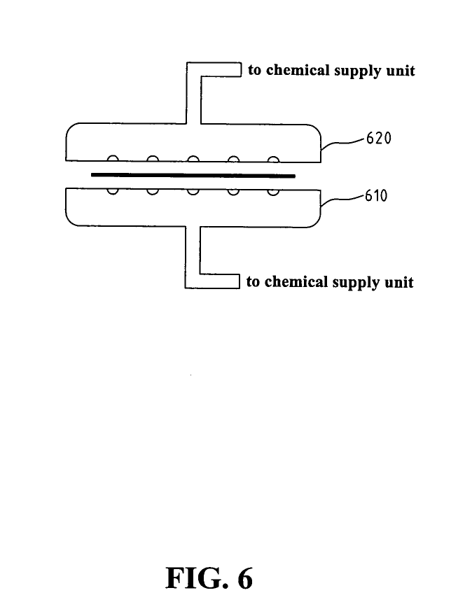

FIG. 6 shows a schematic view of an embodiment of dual-side processing platform of the present invention, including a bottom processing platform 610 and a cover processing platform 620. Bottom processing platform 610 and cover processing platform 620 can have an identical or different design to match the manufacturing requirements. The processed component is sandwiched between bottom processing platform 610 and cover processing platform 620. In addition, both bottom processing platform 610 and cover processing platform 620 are connected to chemical supply unit 220 of FIG. 2 so that control unit 230 of FIG. 2 can control the operations of both bottom processing platform 610 and cover processing platform 620. The advantage of this embodiment is that the manufacturing time of the component can be shortened to improve the production efficiency.

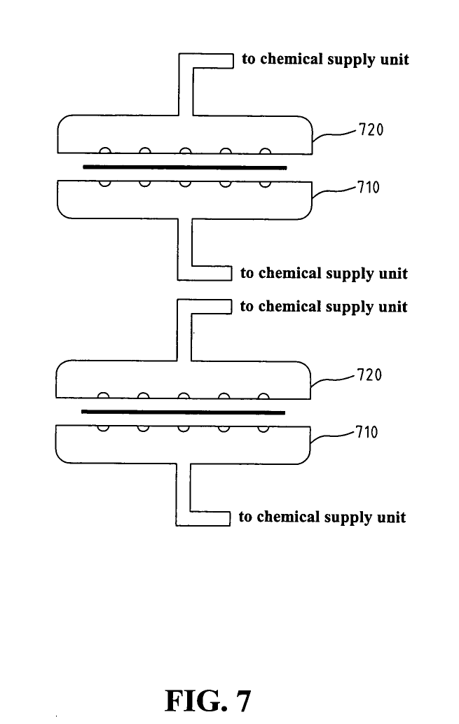

FIG. 7 shows yet another embodiment of a stacked processing platform of the present invention, including a plurality of dual-side processing platforms 710, 720. This embodiment provides additional benefits of space-saving as well as the improvement of production efficiency.

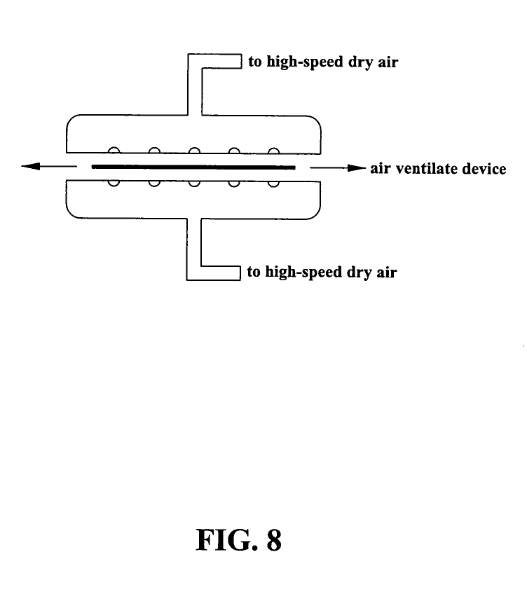

FIG. 8 shows another application of the present invention. In this embodiment, a high speed dry gas, such as nitrogen, is supplied to the processing platform, and an air ventilation device is included to draw the nitrogen gas from the processing platform. As the high speed dry gas flowing through the surfaces between the processed component and the rotating platform, the processed component can be quickly dried.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A system to provide an processing environment for processing a processed component through a plurality of chemical reaction steps, said system moving or rotating said processed component during said chemical reaction steps, said system comprising:
a processing platform, with a platform on which said processed component being processed;
a chemical supply unit, connected to said processing platform and a plurality of chambers containing chemical fluids, water, and air for supplying said chemical fluids, water and air to said processing platform to process or react with said processed component, said chemical fluids, water and air also providing force to move or rotate said processed component during the processes, reacted chemical fluids in said processing platform being collected by said chemical supply unit; and
a control unit, a programmable electronic device for controlling the operations of both said chemical supply unit and said processing platform by inputting the parameters required for said manufacturing process.

2. The system as claimed in claim 1, wherein said processing platform further comprises a plurality of chemical fluid spraying elements on said platform to inject chemical fluids, water and air between said component and said platform.

3. The system as claimed in claim 2, wherein said chemical fluid spraying elements are arranged to match said manufacturing process.

4. The system as claimed in claim 2, wherein said chemical fluid spraying elements are controlled by said control unit to determine the injection of chemical fluids, water and air, including the temperature, speed, volume, location of the injection.

5. The system as claimed in claim 1, wherein said processing platform is a circular processing platform with a rotating platform, where the power to rotate said rotating platform is provided by said chemical fluids, water and air.

6. The system as claimed in claim 1, wherein said processing platform is a conveyor with straight movement where the power to move said conveyor is provided by said chemical fluids, water and air.

7. The system as claimed in claim 1, wherein said processing platform is a circular processing platform with two segments of conveyors with straight movement where the power to move and rotate said platform and said conveyors is provided by said chemical fluids, water and air.

8. The system as claimed in claim 1, wherein said processing platform further comprises a cover platform to form a dual-size processing platform to sandwich said processed component, and said chemical fluids, water and air are injected onto both sides of said processed component.

9. The system as claimed in claim 8, wherein said dual-side processing platform can further be stacked to save processing space.

10. The system as claimed in claim 1, wherein a high speed dry gas can be injected from said chemical supply unit to dry the said process component.

11. A method for manufacturing a processed component with a plurality of chemical reaction steps, applicable to a system with a chemical supply unit, a processing platform and a control unit, said method comprising the steps of:
(a) connecting said chemical supply unit to said processing platform and a plurality of chambers containing chemical fluids, water and air; and
(b) programming said control unit to control said chemical supply unit and said processing platform so that said chemical supply unit injecting said chemical fluids, water, air to said processing platform to provide the power to move or rotate said processed component during said manufacturing process.
